(19) United States
(12) Patent Application Publication
(10) Pub. No.: US 2010/0068983 A1
(43) Pub. Date: Mar. 18, 2010

(54) COOLING SYSTEM FOR ELECTRIC DRIVE MACHINE

(75) Inventor: Matthew E. Williams, East Peoria, IL (US)

Correspondence Address: Caterpillar Inc.;Intellectual Property Dept., AH 9510, 100 N.E. Adams Street, PEORIA, IL, 61629-9510, US

(73) Assignee: Caterpillar Inc., Peoria, IL (US)

(21) Appl. No.: 12/210,466

(22) Filed: Sep. 15, 2008

(51) Int. Cl. H05K 7/20

(52) U.S. Cl. 454/184; 361/695

(57) ABSTRACT

An electric drive machine includes an internal combustion engine remotely coupled to an electrical power generator, which is electrically connected to an electrical components system. The electrical components system is electrically connected to a pair of electric drive motors that are configured to drive wheels of the electric drive machine. A cooling system includes a blower fluidly connected to, and positioned downstream of, the electrical components system. The blower is fluidly connected to, and positioned upstream of, the electrical power generator and the pair of electric drive motors. The cooling system includes a bypass valve operable to control air flow through the electrical components system during certain low power conditions.

### TECHNICAL FIELD

The present disclosure relates generally to an air cooling system, and more particularly to an air cooling system including a blower and ductwork for cooling an electrical components system, an electrical power generator remotely coupled to an internal combustion engine, and a pair of electric drive motors of a machine.

### BACKGROUND

Electric drive systems for large off-highway machines, such as mining trucks, typically include an alternator, or other electrical power generator, driven by an internal combustion engine. The alternator, in turn, supplies electrical power to at least one electric drive motor connected to wheels of the machine. It should be appreciated that a significant amount of heat due to resistive losses is generated during the operation of the electric drive system. Specifically, the alternator and the electric drive motors, along with various other electrical components, may generate a significant amount of heat and, as such, require cooling to prevent damage or failure. However, cooling of these components provides significant challenges due to space limitations and the relative positioning of each of the components. An additional challenge of the cooling system design is to avoid excessive cooling of the electrical components, as well as excessive thermal cycling, which can both lead to premature failure of the electrical components.

U.S. Pat. No. 6,837,322 teaches a ventilation system for an electric drive vehicle utilizing a single centrifugal blower for cooling an alternator, a drive motor, and a control group component. Specifically, the blower is driven by the alternator and is configured to accelerate air in both a radial direction and an axial direction. At least one opening is formed in a perimeter portion of a housing of the blower for receiving the radial airflow, and at least one opening is formed in a side portion of the housing for receiving the axial airflow. Air is routed from these openings to each of the alternator, drive motor, and control group. Although this ventilation system may provide sufficient cooling for an electric drive machine having a specific configuration, it should be appreciated that a variety of electric drive systems exist, each having a unique configuration and, as such, being subject to unique requirements and spatial constraints. It should also be appreciated that the individual electric drive components have different cooling requirements. As a result, there is a continuing need for cooling systems having efficient, flexible designs that fit within limited space constraints of a machine and, further, provide reduced weight and cost.

The present disclosure is directed to one or more of the problems set forth above.

### SUMMARY OF THE DISCLOSURE

In one aspect, a cooling system for an electric drive machine includes an electrical cabinet having an air intake, an electrical cabinet that houses an electrical components system, an ambient air passage, an inlet housing for combining air flow from said air intake and said ambient air passage, and a bypass valve configured to control air flow from said air intake.

In another aspect, an electric drive machine includes a power source electrically connected to an electrical components system, wherein said electrical components system is electrically connected to at least one electric drive motor configured to drive a wheel of the electric drive machine a cooling system having an electrical cabinet having an air intake, an electrical cabinet housing an electrical components system, an ambient air passage, an inlet housing for combining air flow from said air intake and said ambient air passage, and a bypass valve configured to control air flow from said air intake.

In yet another aspect, a method for cooling components of an electric drive machine includes receiving cooling air from an air intake into an electrical cabinet, the electrical cabinet housing an electrical components system, receiving ambient air through an ambient air passage, combining air flow from the air intake and ambient air passage into an inlet housing, and controlling air flow from the air intake using a bypass valve.

### BRIEF DESCRIPTION OF THE DRAWINGS

FIG. 1 is a side diagrammatic view of an electric drive machine, according to the present disclosure;

FIG. 2 is a perspective view of an electric drive propulsion system of the electric drive machine of FIG. 1, including an air cooling system therefor;

FIG. 3 is a perspective view of an inlet of the air cooling system of FIG. 2; and

FIG. 4 is a side diagrammatic view of the electric drive propulsion system, and air cooling system therefor, supported by a frame of the electric drive machine, according to the present disclosure.

FIG. 5 is a diagrammatic representation of the cooling system, showing how the components are in fluid connection with each other and how the controller is in controllable communication with the electrical drivetrain and cooling components.

### DETAILED DESCRIPTION

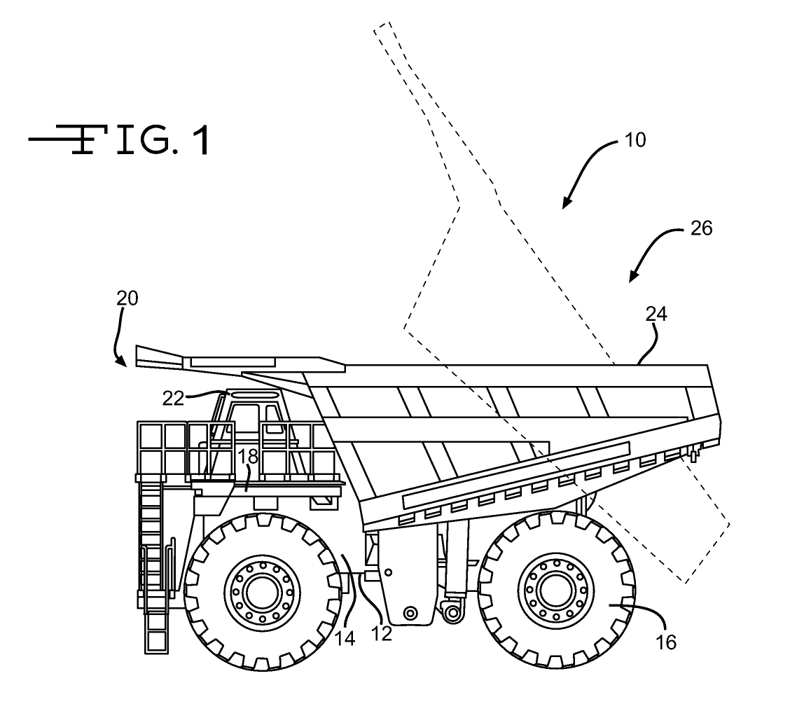

An exemplary embodiment of a machine 10 is shown generally in FIG. 1. The machine 10 may be a mining truck, as shown, or any other off-highway or on-highway vehicle having an electric drive propulsion system. As such, machine 10 may also be referenced herein as an electric drive machine. In the illustrated embodiment, machine 10 generally includes a frame 12 having an electric drive propulsion system 14, discussed later in greater detail, supported thereon for driving wheels of the machine, such as, for example, rear wheels 16 (only one of which is shown). The frame 12 may also support a platform 18 positioned at a front end 20 of the machine 10 and having an operator control station 22 mounted thereon. A dump body 24 is pivotally mounted on the frame 12, at a rear end 26 of the machine 10, such that the dump body 24 is movable between a hauling position, as shown, and a dumping position, shown in phantom.

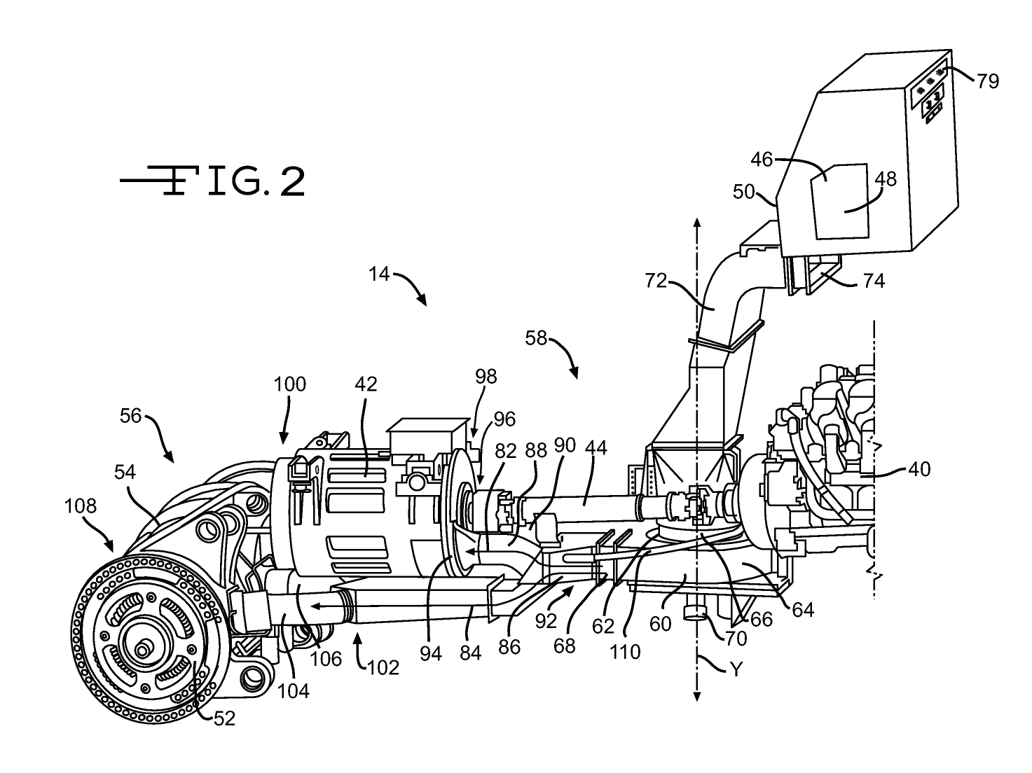

Turning now to FIG. 2, the electric drive propulsion system 14 includes an internal combustion engine 40, such as, for example, a compression or spark-ignited engine, that provides mechanical power to an electrical power generator 42, such as, for example, an alternator. As shown in the illustrated embodiment, the electrical power generator 42 may be remotely coupled to the internal combustion engine 40, such as through a drive shaft 44. According to one embodiment, the electrical power generator 42 may be mounted to the frame 12, rather than directly to or in close proximity to the internal combustion engine 40, to more evenly distribute weight across the frame 12 of the machine 10. Alternatively, however, the electrical power generator 42 may be belt-driven or directly attached to the internal combustion engine 40, as is well known in the art. The electrical power generator 42, in turn, produces electrical power, such as, for example, an alternating electrical current.

It should be appreciated that one or more rectifiers (not shown) may also be used to convert the alternating electrical current to a direct electrical current, as necessary. Alternatively, however, a direct electrical current may be produced and converted to an alternating electrical current, using an inverter 46. According to one embodiment, the electrical power generator 42 may be electrically connected to an electrical components system 48 that may include the inverter 46. The inverter 46, along with other electrical components of the electrical components system 48, may be positioned within an electrical cabinet 50, or other suitable housing. Referring also to FIG. 1, the electrical cabinet 50 may be supported on the platform 18 of the machine 10 and, further, may be positioned adjacent the operator control station 22.

The inverter 46 may condition the electrical power produced by the electrical power generator 42 to provide a voltage and current sufficient to power one or more motors, such as, for example, a pair of electric drive motors 52 (only one of which is shown). According to one example, the inverter 46 may modulate the frequency of the power produced by the electrical power generator 42 to control the speed of the pair of electric drive motors 52. The electric drive motors 52 may be, for example, wheel motors used to power rear wheels 16, shown in FIG. 1, to propel the machine 10. It should be appreciated that the electric drive motors 52 may be disposed within a central axle housing 54 of a rear axle assembly 56. Although portions of the rear axle assembly 56 have been removed for illustrative purposes, it should be appreciated that the rear axle assembly 56 may typically include additional components, such as, for example, a final drive assembly and a wheel hub.

The machine 10 also includes an air cooling system, referenced generally at 58, for cooling the components of the electric drive propulsion system 14. The air cooling system 58 includes a blower 60 fluidly connected, such as through ductwork, to the electrical components system 48, the electrical power generator 42, and the pair of electric drive motors 52. Specifically, the blower 60 may be a centrifugal blower and may include an impeller 62 rotatable about a first axis Y. The blower 60 may also include a blower housing 64 having an axially positioned inlet 66 and a radially positioned outlet 68.

The electrical cabinet 50 includes air intake 79 and electrical components system 48. Ambient air may enter electrical cabinet 50 through air intake 79, providing cooling for electrical components system 48. In one embodiment, air intake 79 is positioned at a front side 78 of electrical cabinet 50. Ambient air may be drawing into an inlet housing 76 through the electrical cabinet 50. Additionally, inlet housing 76 receives ambient air directly from the atmosphere through ambient air passage 74. It should be appreciated that the ambient air passage 74 may be positioned above the platform 18 at the front end 20 of the machine 10 (FIG. 1). As such, it should also be appreciated that the ambient air drawn through the ambient air passage 74 is substantially unobstructed, and provides an air flow into inlet duct 72 that is not heated by the electrical components system 48.

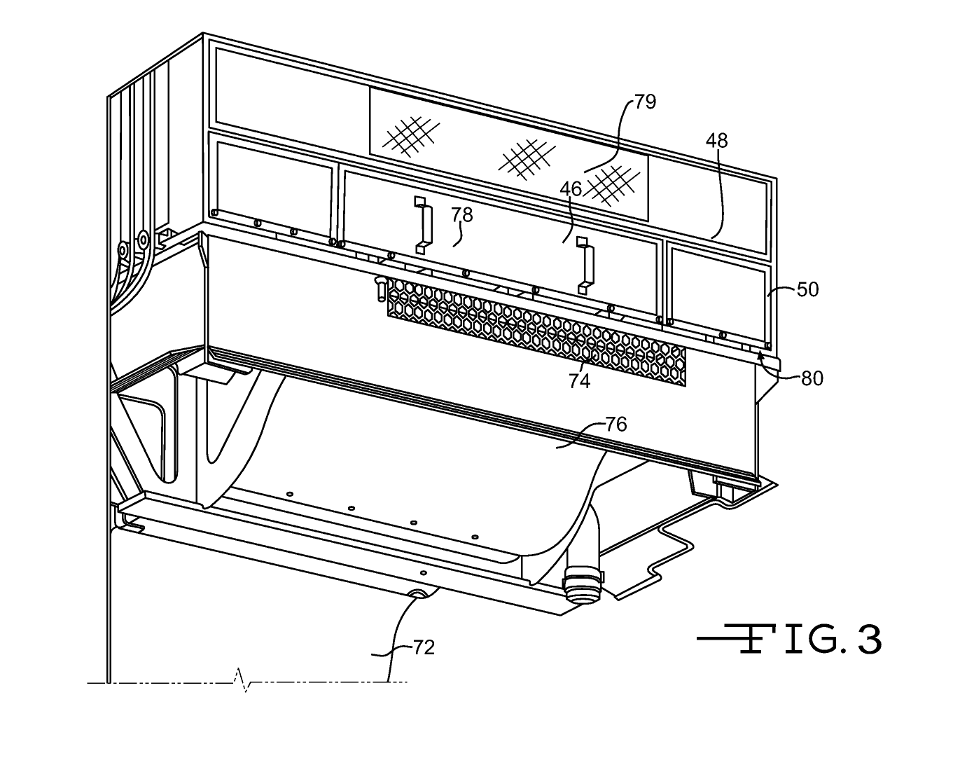

An inlet duct 72, made of metal or flexible material, or other fluid passage, may fluidly connect the blower 60 to both of the electrical cabinet 50, described above, and an ambient air passage 74, shown in greater detail in FIG. 3. Air from both air intake 79 and ambient air passage 74 may join at a point in the cooling system (not shown), such as in inlet housing 76.

The cooling system further comprises a bypass valve 75. Bypass valve 75 prevents or restricts the flow of air from air intake 79 to inlet housing 76. For example, bypass valve 75 may prevent or restrict the flow of air through electrical cabinet 50. In one embodiment, the bypass valve is oriented between air intake 79 and inlet housing 76, such as within electrical cabinet 50 and after electrical components system 48. Alternatively, bypass valve 75 may be positioned between air intake 79 and electrical components system 48, such as adjacent to air intake 79. In yet another embodiment, bypass valve 75 may be positioned external to electrical cabinet 50, such as on the ambient air intake side of air intake 79.

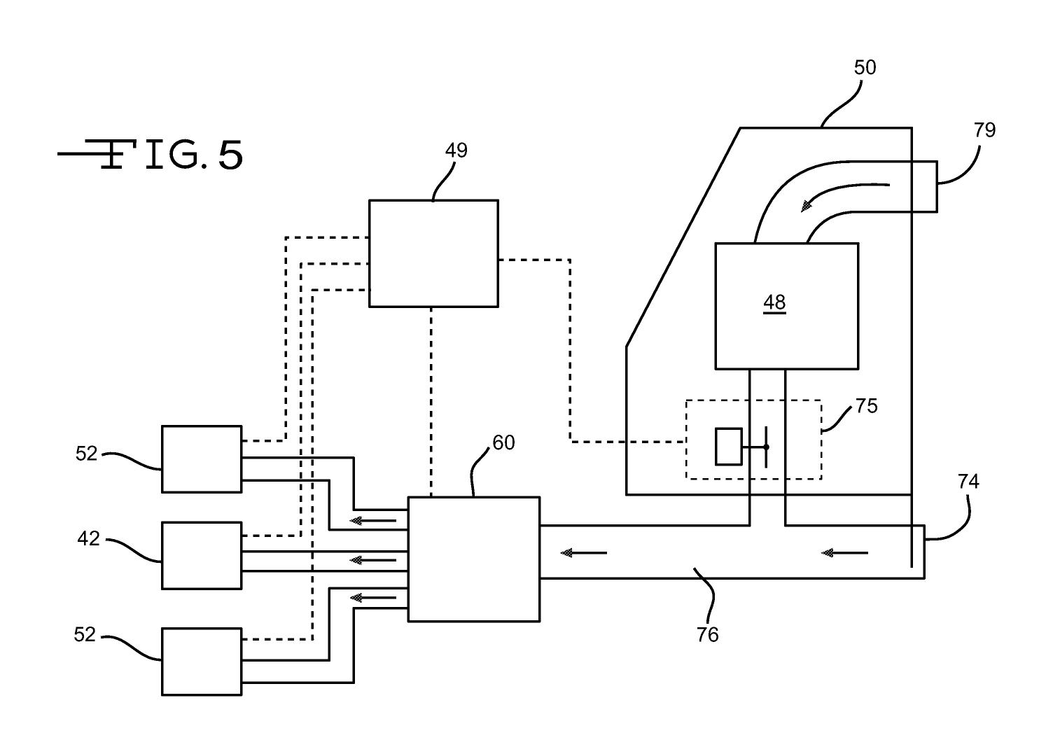

As depicted in FIG. 5, bypass valve 75 is shown positioned after electrical cabinet 50 and is shown as a butterfly valve in an open position. However, it should be understood that bypass valve 75 can be any suitable valve known in the art. For example, bypass valve 75 may be a flapper valve, butterfly valve, or gate valve. Further, bypass valve 75 is operatively connected to the controller 49, which controls the orientation of the bypass valve via, e.g., a valve actuator (not shown). Bypass valve 75 can be operated electrically or fluidly, as is known in the art.

Referring again to FIG. 2, it should be appreciated that, since the electrical cabinet 50 is positioned upstream of the blower 60, the electrical components system 48 housed therein may be cooled using ambient air drawn through the electrical cabinet 50 by the blower 60. It should also be appreciated that the ambient air drawn through the electrical cabinet 50 may become heated as it passes over the electrical components system 48. This heated air is combined with the ambient air provided directly from the atmosphere through the ambient air passage 74, as described above, and pressurized by the blower 60.

The pressurized ambient air may be directed from the blower 60 through one or more outlet ducts, or other fluid passages, to cool the electrical power generator 42 and the electric drive motors 52. According to one embodiment, the pressurized ambient air may travel along a first fluid path 82 to cool the electrical power generator 42 and a second fluid path 84 to cool the electric drive motors 52. It should be appreciated that the electrical power generator 42 and the electric drive motors 52, according to the illustrated embodiment, may be fluidly in parallel, i.e., both components receive pressurized ambient air along fluid paths 82 and 84 that may be substantially parallel or inclined toward one another. Initially, however, both of the first and second fluid paths 82 and 84 are directed through a common passage or, more specifically, an intermediate duct 86.

The intermediate duct 86, designed to provide a required flow split of air between the electrical power generator 42 and the electric drive motors 52, may be fluidly connected to the electrical power generator 42 through at least two fluid passages, or ducts, 88 and 90. Fluid passages 88 and 90 may extend from a first end 92 of the intermediate duct 86 and terminate in two quadrants 94 and 96 at a first end 98 of the electrical power generator 42. According to the illustrated embodiment, the fluid passages 88 and 90 may direct pressurized ambient air toward two lower quadrants 94 and 96 of the electrical power generator 42. However, it should be appreciated that one or more passages may be provided to direct pressurized ambient air toward any portion of the electrical power generator 42. The pressurized ambient air, passing through and cooling the electrical power generator 42, may be exhausted through a second end 100 of the electrical power generator 42.

A second end 102 of the intermediate duct 86 may be fluidly connected to the central axle housing 54 through at least two fluid passages, or ducts, 104 and 106. Although two fluid passages 104 and 106 are shown, it should be appreciated that any number of fluid passages may be used to direct pressurized air toward the electric drive motors 52. According to the illustrated embodiment, each of the fluid passages 104 and 106 may be directed toward one of the pair of electric drive motors 52. According to one embodiment, it may be desirable to dimension the intermediate duct 86 so that a cross sectional area of the second end 102 is greater than a cross sectional area of the first end 92. As such, the pressurized ambient air may maintain sufficient pressure as it diverges through the fluid passages 104 and 106. After cooling the electric drive motors 52, the pressurized ambient air may pass through one or more exhaust outlets positioned at a back end 108 of the rear axle assembly 56.

The air cooling system 58 may also include a positive pressure line 110 fluidly connected to the intermediate duct 86, such as at the first end 92 thereof, and the electrical components system 48. Specifically, the positive pressure line 110 may direct pressurized ambient air, or even filtered pressurized ambient air, from the intermediate duct 86 and into the electrical components system 48 to create a positive pressure therein. As a result, dust particles carried by the ambient air that is drawn through a portion of the electrical cabinet 50 by the blower 60 may be prevented from entering, and perhaps contaminating, the electrical components housed within the electrical components system 48. This pressurized section may release pressure periodically, thereby cooling the electrical components within the electrical components system 48.

The air cooling system 58 may be designed and configured to provide adequate cooling of each component of the electric drive propulsion system 14 during an extreme operating condition of the machine 10. For example, the blower 60 may be sized and, further, may be driven at a speed and frequency for cooling each of the electrical components system 48, the electrical power generator 42, and the electric drive motors 52 during such an extreme operating condition. According to one embodiment, a control algorithm may be used to control operation of the air cooling system 58.

Specifically, controller 49, such as an electronic control module for the electric drive propulsion system 14, may communicate with a sensor, such as, for example, a resistance temperature detector, associated with each of the electrical components system 48, the electrical power generator 42, and the electric drive motors 52. The controller may monitor the temperatures of the respective components and ensure that the temperatures are maintained below desirable limits. If it is determined that one of the electrical components system 48, the electrical power generator 42, and the electric drive motors 52 requires cooling, the controller may initiate or alter operation of the blower 60. According to one embodiment, the blower 60 may be operated at a plurality of speeds, such as, for example, a low speed and a high speed. It should be appreciated, however, that various control strategies are contemplated for use with the air cooling system 58.

### INDUSTRIAL APPLICABILITY

The present disclosure finds potential application in any machine that utilizes an electric drive propulsion system. Further, the disclosure may be specifically applicable to an electric drive machine having an internal combustion engine coupled to a pair of electric drive motors via a remotely mounted electrical power generator. Yet further, the present disclosure may be applicable to electric drive propulsion systems for machines having significant cooling requirements and strict spatial constraints. Such machines may include, but are not limited to, off-highway machines, such as mining trucks, on-highway machines, such as buses and trucks, and other machines known in the art.

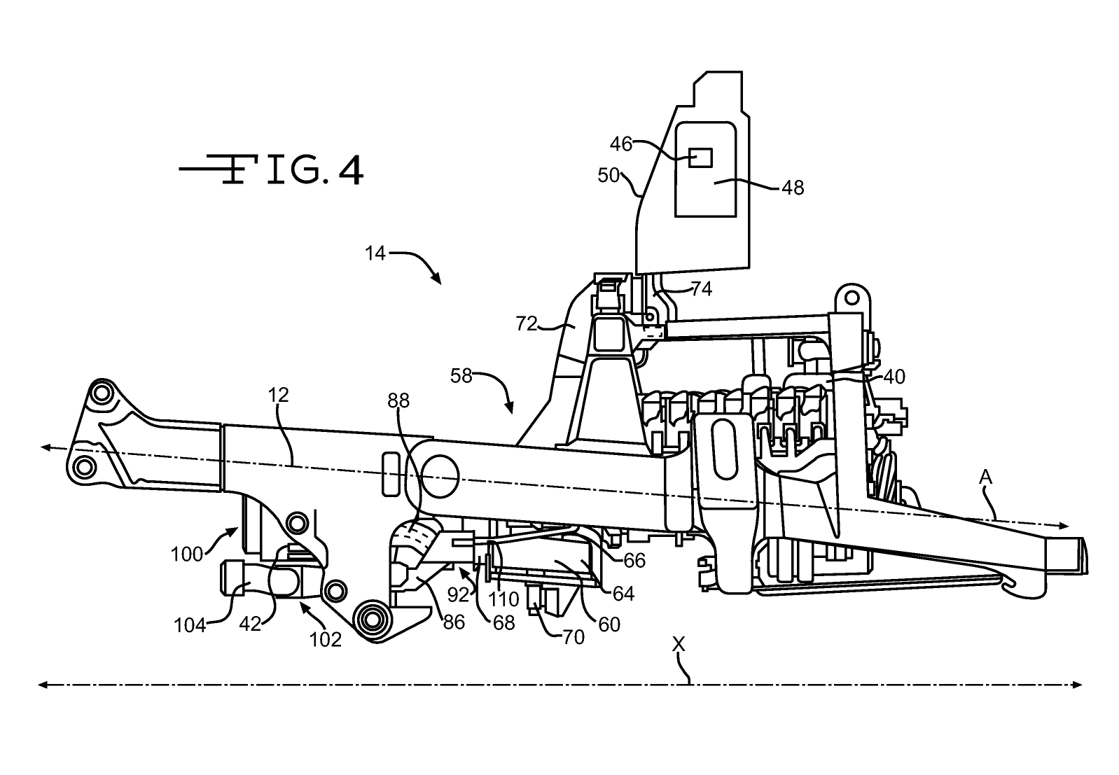

Referring generally to FIGS. 1-4, a machine 10 may include a frame 12 having an electric drive propulsion system 14 supported thereon for driving rear wheels 16 of the machine 10. The electric drive propulsion system 14 may include an internal combustion engine 40 that provides mechanical power to an electrical power generator 42, such as, for example, an alternator. The electrical power generator 42, in turn, may produce electrical power, such as, for example, an alternating electrical current. The frequency of the alternating electrical current may be modulated using an inverter 46 of an electrical components system 48. The electrical components system 48 may be electrically connected to a pair of electric drive motors 52 used to power the rear wheels 16 of the machine 10.

It should be appreciated that, during operation of the machine 10, the electrical power generator 42 and the electric drive motors 52, along with the electrical components system 48, may generate a significant amount of heat and, as such, require cooling to prevent damage or failure. The air cooling system 58, as described herein, may be used to cool each of the electrical components system 48, the electrical power generator 42, and the electric drive motors 52 using a blower 60 and the ductwork described herein. Specifically, the blower 60, using a rotatable impeller 62 powered by a hydraulic motor 70, may cool the electrical components system 48 using ambient air drawn from air intake 79 through an electrical cabinet 50, housing the electrical components system 48.

In one mode, the blower 60 may draw air through both of the air intake 79 and an ambient air passage 74 positioned to receive ambient air directly from the atmosphere. The combined air is drawn into the blower 60 through an inlet duct 72 and pressurized. Further, the bypass valve 75 may prevent or restrict the flow of air from the air intake 79, allowing the remaining air in inlet duct 72 to be drawn from ambient air passage 74. The pressurized ambient air may travel along a first fluid path 82 to cool the electrical power generator 42 and a second fluid path 84 to cool the electric drive motors 52. It should be appreciated that the first fluid path 82 extends from the blower 60, through an intermediate duct 86, and through two diverging channels 88 and 90. The second fluid path 84 may extend from the blower 60, through the intermediate duct 86, and through channels 104 and 106. It may be desirable to align an outlet 68 of the blower 60 with a higher resistance component, such as the electrical power generator 42, to direct a majority of an air flow from the blower 60 thereto.

The air cooling system 58 may be designed and configured to provide adequate cooling of each component of the electric drive propulsion system 14 during an extreme operating condition of the machine 10. Further, the air cooling system 58 may be operated using any known control algorithm. As such, the air cooling system 58, described herein, provides efficient cooling of the components of the electric drive propulsion system 14 using a system occupying limited space and having reduced weight and cost.

It should be appreciated that the components of the electric drive propulsion system will experience different levels of heat generation during different portions of its operating cycle. For instance, acceleration, hill climbing, and retarding will generate maximum levels of heat generation in the electric drive propulsion system. Conversely, periods of idling generate almost no heat generation in the components of the electric drive propulsion system. The air cooling system 58 is designed to accommodate the entire range of operating cycles.

It should also be appreciated that different components of the electric drive propulsion system have different cooling needs. The motor(s) and generator, for example, have a much higher thermal mass than the electrical components system. The motor(s) and generator therefore require cooling air for a period of time even when the electric drive propulsion system is no longer generating power, e.g. idling. The electrical components system has a much smaller thermal mass, however, and does not require as much cooling air during idling conditions. In addition, it is well known that unnecessary thermal cycles are detrimental to the longevity of the electrical components system. Both the frequency of the cycles and the depth of the cycles are factors that must be accounted for in ensuring the longevity of the electrical components system. The air cooling system 58 addresses these issues by the use of the bypass valve 75. The valve can remain open during maximum levels of heat generation in order to adequately cool the electrical components system. The valve can then close, at least partially, during periods of minimum heat generation in order to prevent unnecessary thermal cycling of the electrical components system.

Controller 49 receives inputs from the electric drive propulsion system. Based on these inputs, or upon internal maps, the controller can operate bypass valve 75 to be oriented in an open, closed, or partial or intermediate position.

For example, the controller 49 could process a power command. The power command could correspond to power required to or from the electrical motors or the generator. In one embodiment, the controller 49 closes the bypass valve when the power command is at or near zero. In another embodiment, the controller compares the operating temperature of the electrical components system to a maximum temperature limit Tmax. If the operating temperature is above Tmax, the controller 49 does not close, or does not fully close, the bypass valve 75.

It should be understood that the above description is intended for illustrative purposes only, and is not intended to limit the scope of the present disclosure in any way. Thus, those skilled in the art will appreciate that other aspects of the disclosure can be obtained from a study of the drawings, the disclosure and the appended claims.

What is claimed is:

1. A cooling system for an electric drive machine comprising:
an electrical cabinet having an air intake, said electrical cabinet housing an electrical components system,
an ambient air passage,
an inlet housing for combining air flow from said air intake and said ambient air passage, and
a bypass valve configured to control air flow from said air intake.

2. The cooling system in claim 1 wherein a controller is operatively connected to said bypass valve.

3. The cooling system in claim 2 wherein the electrical components system includes an inverter.

4. The cooling system in claim 3 wherein the electrical components system includes a rectifier.

5. The cooling system in claim 1 wherein said bypass valve is located within electrical cabinet and fluidly downstream of electrical components system.

6. The cooling system in claim 1 including a blower fluidly connected to and positioned downstream of the electrical components system, wherein said blower is fluidly connected to and positioned upstream of an electrical power generator and an electric drive motor.

7. The cooling system in claim 6 wherein said blower is driven by a hydraulic motor.

8. An electric drive machine comprising:
a power source electrically connected to an electrical components system, wherein said electrical components system is electrically connected to at least one electric drive motor configured to drive a wheel of the electric drive machine;
a cooling system having:
an electrical cabinet having an air intake, said electrical cabinet housing said electrical components system,
an ambient air passage,
an inlet housing for combining air flow from said air intake and said ambient air passage, and
a bypass valve configured to control air flow from said air intake.

9. The electric drive machine in claim 8 wherein a controller operatively connected to said bypass valve.

10. The electric drive machine in claim 8 wherein the power source is an internal combustion engine coupled to an electrical power generator.

11. The electric drive machine in claim 8 wherein said bypass valve does not allow cooling air flow to said electrical components system during idling conditions.

12. The electric drive machine in claim 9 wherein said bypass valve allows ambient air flow to said electrical power generator and said electric drive motor during idling conditions.

13. A method for cooling components of an electric drive machine comprising:
receiving cooling air from an air intake into an electrical cabinet, said electrical cabinet housing an electrical components system,
receiving ambient air through an ambient air passage,
combining air flow from said air intake and said ambient air passage into an inlet housing, and
controlling air flow from said air intake using a bypass valve.

14. The method in claim 13 wherein a controller is operatively connected to said bypass valve.

15. The method in claim 13 wherein the electrical components system includes an inverter.

16. The method in claim 13 wherein the electrical components system includes an rectifier.

17. The method in claim 13 wherein said bypass valve is located within electrical cabinet and fluidly downstream of electrical components system.

18. The method in claim 13 including a blower fluidly connected to and positioned downstream of the electrical components system, wherein said blower is fluidly connected to and positioned upstream of an electrical power generator and an electric drive motor.

19. The method in claim 18 including driving said blower by a hydraulic motor.
